(19) United States
(12) Patent Application Publication
(10) Pub. No.: US 2015/0146752 A1
(43) Pub. Date: May 28, 2015

(54) LIGHT EMITTING DEVICE AND IMAGE DISPLAY APPARATUS

(71) Applicant: Seiko Epson Corporation, Tokyo (JP)

(72) Inventor: Tomio IKEGAMI, Chino (JP)

(21) Appl. No.: 14/548,748

(22) Filed: Nov. 20, 2014

(30) Foreign Application Priority Data
Nov. 25, 2013 (JP) 2013-243182

(51) Int. Cl. H01S 5/026; G02B 27/01

(52) U.S. Cl. CPC H01S 5/0261; G02B 27/0172
USPC 372/38.07

(57) ABSTRACT

A light emitting device includes: a light emitting element; and a temperature variable resistive element which is connected to the light emitting element in parallel and is provided so that heat of the light emitting element can be conducted, wherein the temperature variable resistive element has a characteristic in which a resistance value decreases as a temperature increases.

### BACKGROUND

1. Technical Field

The present invention relates to a light emitting device and an image display apparatus.

2. Related Art

A head-mounted display (HMD) is known as a display apparatus which directly irradiates the retina of the eyes with laser and allows a user to visually confirm an image.

In general, the head-mounted display includes: a light emitting device which emits light; and a scanning unit which changes an optical path so that the emitted light is scanned on the retina of a user. By the head-mounted display, the user can visually confirm, for example, both a background color of the outside and the image which is drawn by the scanning unit at the same time.

However, in the head-mounted display, since the retina is irradiated with the light emitted from the light emitting device, it is necessary to consider that the retina does not get damaged by the light. In general, safety is secured by limiting an output of the light emitting device so that an amount of the light emitted from the light emitting device does not exceed regulatory limits.

In JP-A-6-151958, in order to control a light emitting output, a light emitting device which is provided with a resistor which controls a current that flows in a light emitting element is disclosed. In the light emitting device, since an element having a characteristic of increasing a temperature and a resistance value is used as the resistor, even if the temperature of the light emitting element increases by self-heating or changing of the ambient temperature, and light emitting efficiency of the light emitting element deteriorates, it is possible to increase a ratio of the current which flows in the light emitting element by making a configuration in which the current that flows in the resistor is reduced according to the temperature increase in the light emitting element. For this reason, it is possible to compensate for the deterioration of the light emitting efficiency, and to always obtain a predetermined light emitting output.

However, in the display apparatus described in JP-A-6-151958, it is possible to prevent the light emitting output from being largely deteriorated, but it is not possible to prevent the light emitting output from being largely increased. For this reason, if a failure or the like is generated on a current supply circuit, and the current becomes too high, there is a concern that the light emitting output exceeds a presumed range.

### SUMMARY

An advantage of some aspects of the invention is to provide a light emitting device having a high level of safety in which an amount of light is suppressed to be equal to or less than a certain value, and an image display apparatus having a high level of safety which is provided with the related light emitting device.

The invention can be implemented as the following application examples.

### APPLICATION EXAMPLE 1

This application example is directed to a light emitting device including: a light emitting element; and a temperature variable resistive element which is connected to the light emitting element in parallel and is provided so that heat of the light emitting element can be conducted. The temperature variable resistive element has a characteristic in which a resistance value decreases as the temperature increases.

With this configuration, since an amount of light emitted from the light emitting device can be suppressed to be equal to or less than a certain value without using an electronic circuit or the like, a light emitting device having a much higher level of safety can be obtained.

### APPLICATION EXAMPLE 2

In the light emitting device according to the application example described above, it is preferable that the light emitting device further includes an insulator having a thermal conductivity, which is provided between the light emitting element and the temperature variable resistive element.

With this configuration, it is possible to prevent a failure, such as a short circuit between the light emitting element and the temperature variable resistive element from being generated, and to enhance the thermal conductivity. As a result, it is possible to reduce a time difference between the light emitting element and the temperature variable resistive element when the temperature increases, and to obtain a light emitting device having a much higher level of safety.

### APPLICATION EXAMPLE 3

In the light emitting device according to the application example described above, it is preferable that the light emitting element and the temperature variable resistive element are overlapped with each other.

With this configuration, it is possible to conduct the heat generated from the light emitting element to the temperature variable resistive element almost without a dissipation of the heat. For this reason, an amount of heat which can be consumed in increasing the temperature of the temperature variable resistive element becomes much larger, and as a result, it is possible to increase a rate of temperature increase of the temperature variable resistive element, and to reduce the time difference between the light emitting element and the temperature variable resistive element when the temperature increases.

### APPLICATION EXAMPLE 4

In the light emitting device according to the application example described above, it is preferable that the light emitting element has a shape of a rectangle in a planar view, and the temperature variable resistive element is provided along a first side surface which corresponds to one side of the rectangle and a second side surface which is adjacent to the first side surface.

With this configuration, between the light emitting element and the temperature variable resistive element, an area in which the light emitting element and the temperature variable resistive element face each other becomes large, and an area which contributes to the thermal conductivity between the light emitting element and the temperature variable resistive element also becomes much larger. For this reason, it is possible to increase an amount of heat conduction. As a result, it is possible to reduce the time difference between the light emitting element and the temperature variable resistive element when the temperature increases, and to obtain a light emitting device having a much higher level of safety.

### APPLICATION EXAMPLE 5

In the light emitting device according to the application example described above, it is preferable that the light emitting element has a shape of a rectangle in a planar view, and the temperature variable resistive element is provided along the first side surface which corresponds to one side of the rectangle, the second side surface which is adjacent to the first side surface, and a third side surface which is adjacent to the second side surface.

With this configuration, between the light emitting element and the temperature variable resistive element, the area in which the light emitting element and the temperature variable resistive element face each other becomes much larger, and the area which contributes to the heat conduction between the light emitting element and the temperature variable resistive element also becomes much larger. For this reason, it is possible to increase the amount of the heat conduction. As a result, it is possible to further reduce the time difference between the light emitting element and the temperature variable resistive element when the temperature increases, and to obtain a light emitting device having a much higher level of safety. In addition, since the temperature variable resistive element is provided to surround the light emitting element, a position shift of the light emitting element and the temperature variable resistive element is unlikely to occur. For this reason, even when a vibration or the like is applied, it is easy to maintain the thermal conductivity between the light emitting element and the temperature variable resistive element, and efficiency is extremely high in the viewpoint of securing safety.

### APPLICATION EXAMPLE 6

In the light emitting device according to the application example described above, it is preferable that the light emitting element is an edge emitting type element which emits the light from both a front end surface and a rear end surface, and the temperature variable resistive element is provided along the rear end surface.

With this configuration, the temperature variable resistive element is irradiated with the light emitted from the rear end surface, and causes the increase in temperature of the temperature variable resistive element in accordance with a light absorption. For this reason, not only the heat conduction from the light emitting element, but also the light absorption is applied to a process of the temperature increase of the temperature variable resistive element. As a result, it is possible to increase the rate of temperature increase of the temperature variable resistive element, and to further reduce the time difference between the light emitting element and the temperature variable resistive element when the temperature increases.

### APPLICATION EXAMPLE 7

In the light emitting device according to the application example described above, it is preferable that the light emitting element is a surface emitting type element, and the temperature variable resistive element surrounds the side surfaces of the light emitting element.

With this configuration, between the light emitting element and the temperature variable resistive element, the area in which the light emitting element and the temperature variable resistive element face each other becomes large. For this reason, the area which contributes to the heat conduction between the light emitting element and the temperature variable resistive element also becomes large, and the amount of heat conduction can be increased. As a result, it is possible to reduce the time difference between the light emitting element and the temperature variable resistive element when the temperature increases, and to further reduce emitting time of light having an amount which adversely affects the retina.

### APPLICATION EXAMPLE 8

In the light emitting device according to the application example described above, it is preferable that the light emitting device further includes a mount on which the light emitting element and the temperature variable resistive element are mounted.

With this configuration, while a part of the heat from the light emitting element is conducted to the temperature variable resistive element, the heat is also conducted to the mount. The mount can generally contribute to dissipating the heat of the light emitting element since the mount has a relatively high heat capacity.

### APPLICATION EXAMPLE 9

In the light emitting device according to the application example described above, it is preferable that the light emitting device further includes a detection portion which is connected to the temperature variable resistive element in series and detects an amount of the current which flows in the temperature variable resistive element.

With this configuration, since the amount of the current which flows through a line on the light emitting element side can be estimated, it is possible to indirectly assume the amount of light of the light emitting element. As a result, it is possible to easily find the amount of light of the light emitting element. In addition, when the light emitting device is embedded in the image display apparatus, in the image display apparatus, it is possible to obtain data for comparing a current value which is assigned to the light emitting device by the control portion and a current value which flows in the light emitting element in practice. For this reason, for example, it is possible to perform an inspection for confirming an integrity of the light emitting element.

### APPLICATION EXAMPLE 10

This application example is directed to an image display apparatus including: a current source; and the light emitting device according to the application example.

With this configuration, the light emitting device which can suppress the amount of light emitted from the light emitting device to be equal to or less than a certain value is provided without using the electronic circuit or the like. For this reason, an image display apparatus having a much higher level of safety can be obtained.

### BRIEF DESCRIPTION OF THE DRAWINGS

The invention will be described with reference to the accompanying drawings, wherein like numbers reference like elements.

FIG. 1 is a view illustrating a schematic configuration of an embodiment (head-mounted display) of an image display apparatus according to the invention.

FIG. 2 is a partially enlarged view of the image display apparatus illustrated in FIG. 1.

FIG. 3 is a schematic configuration view of a signal generation portion of the image display apparatus illustrated in FIG. 1.

FIG. 4 is a view illustrating a schematic configuration of a light scanning portion illustrated in FIG. 3.

FIG. 5 is a view illustrating an operation of the light scanning portion illustrated in FIG. 4.

FIG. 6 is a perspective view illustrating a schematic configuration of a first embodiment (light source) of a light emitting device according to the invention.

FIG. 7 is a circuit diagram illustrating an example of connection between the light emitting device illustrated in FIG. 6 and a current source.

FIG. 8 is a schematic view illustrating a difference of a relationship between a driving current and an amount of light of the light emitting element, according to a presence or an absence of a temperature variable resistive element.

FIG. 9 is a perspective view illustrating a second embodiment of the light emitting device according to the invention.

FIG. 10 is a perspective view illustrating a third embodiment of the light emitting device according to the invention.

FIG. 11 is a perspective view illustrating a fourth embodiment of the light emitting device according to the invention.

FIG. 12 is a perspective view illustrating a fifth embodiment of the light emitting device according to the invention.

FIG. 13 is a perspective view illustrating a sixth embodiment of the light emitting device according to the invention.

### DESCRIPTION OF EXEMPLARY EMBODIMENTS

Hereinafter, a light emitting device and an image display apparatus will be described in detail based on appropriate embodiments illustrated in attached drawings.

### Image Display Apparatus

First, an embodiment of the image display apparatus according to the invention will be described.

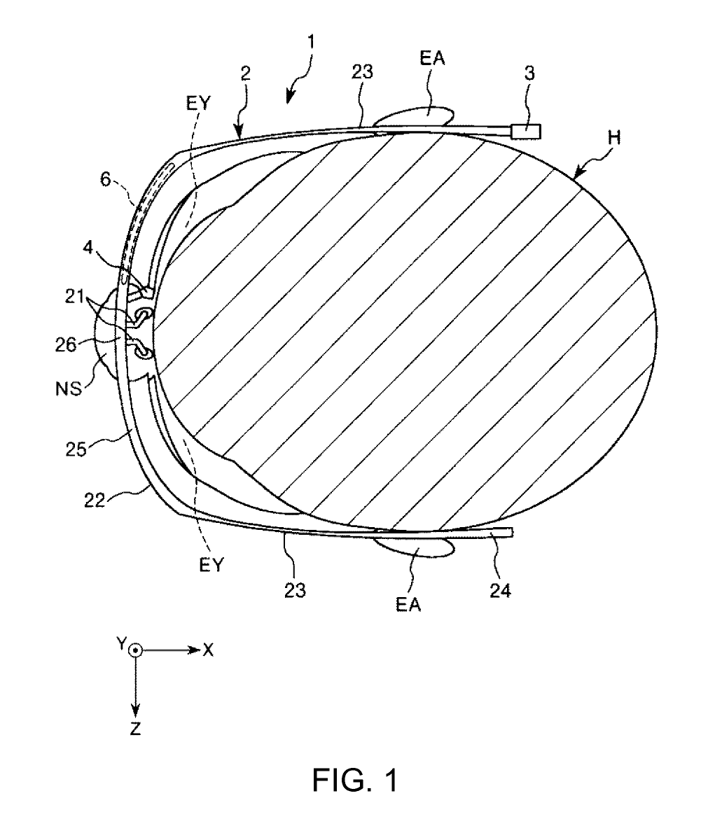

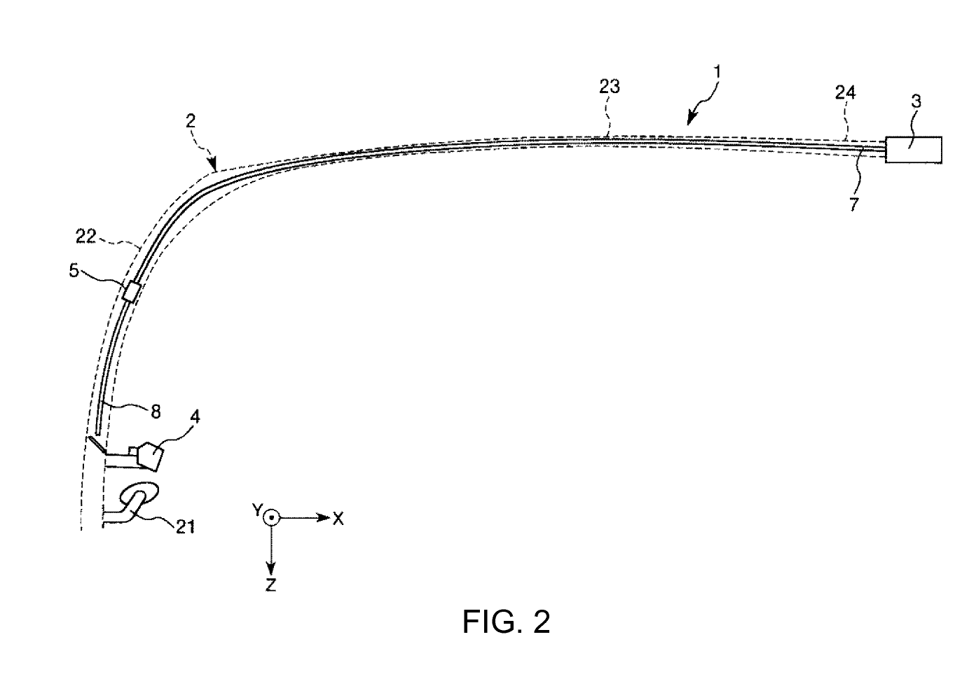

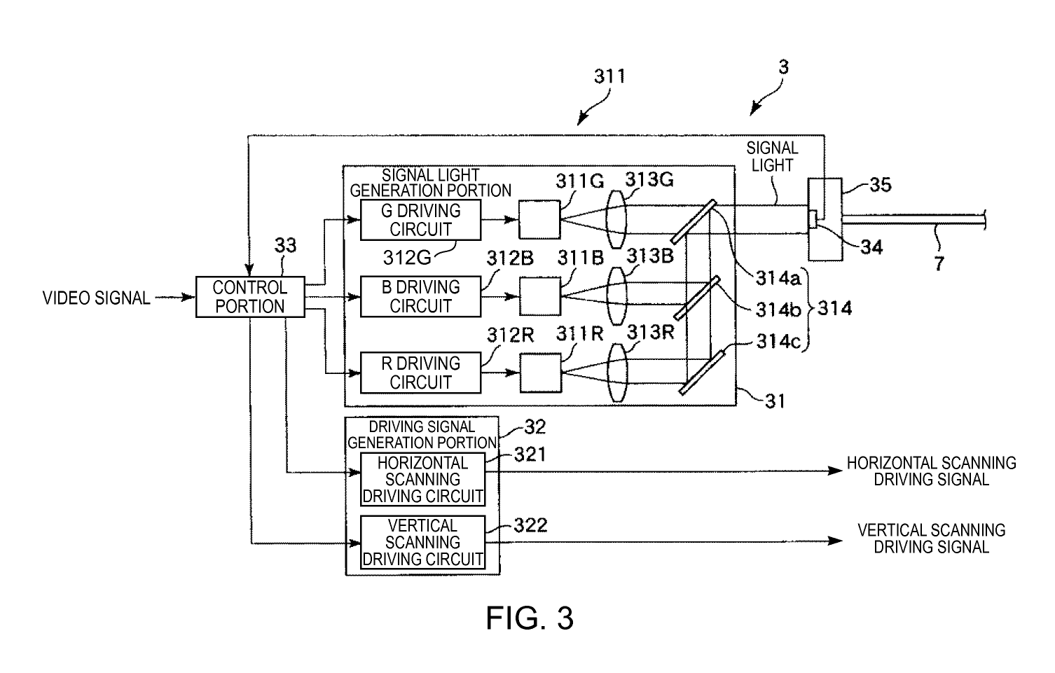

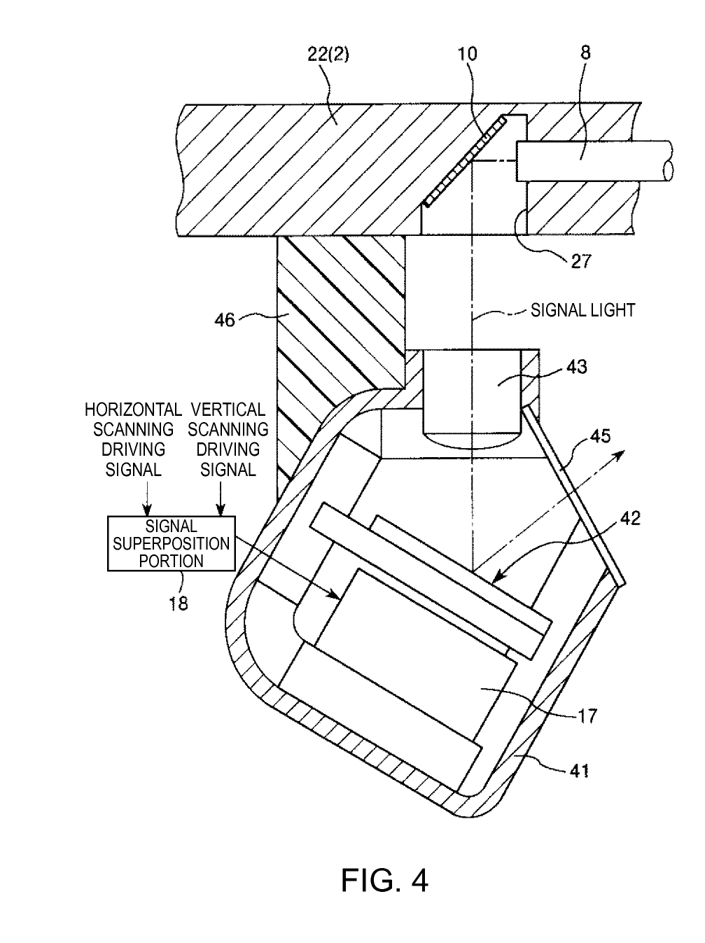

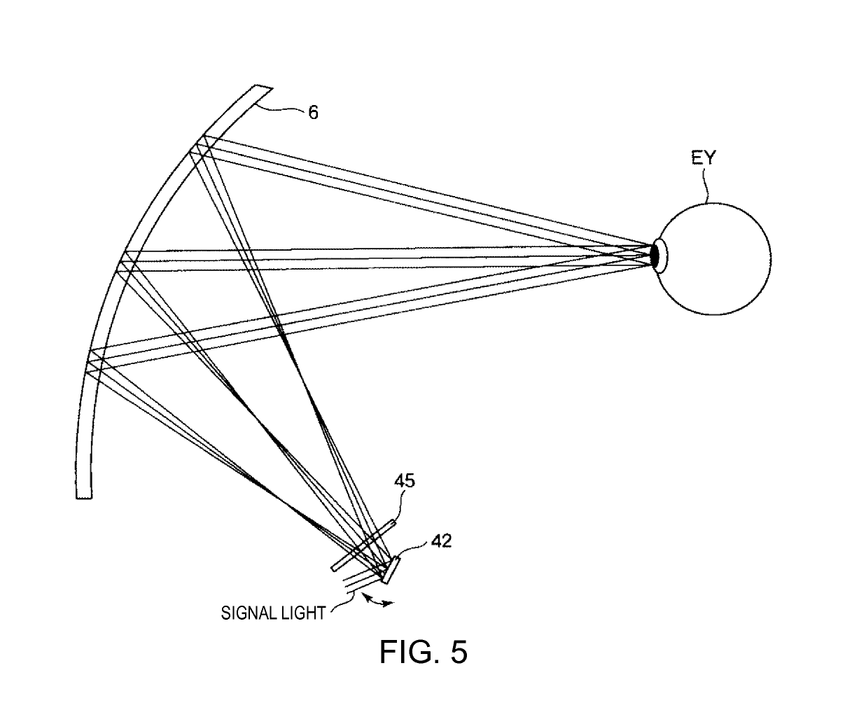

FIG. 1 is a view illustrating a schematic configuration of the embodiment (head-mounted display) of the image display apparatus according to the invention. FIG. 2 is a partially enlarged view of the image display apparatus illustrated in FIG. 1. In addition, FIG. 3 is a schematic configuration view of a signal generation portion of the image display apparatus illustrated in FIG. 1. FIG. 4 is a view illustrating a schematic configuration of a light scanning portion illustrated in FIG. 3. FIG. 5 is a view illustrating an operation of the light scanning portion illustrated in FIG. 4.

In addition, in FIG. 1, for convenience of description, an X axis, a Y axis, and a Z axis are illustrated as three axes which are perpendicular to each other. Tip end sides of arrows of the axes are “+ (positive)”, and base end sides of the arrows of the axes are “− (negative)”. In addition, a direction which is parallel to the X axis is an “X axis direction”, a direction which is parallel to the Y axis is a “Y axis direction”, and a direction which is parallel to the Z direction is a “Z axis direction”.

Here, when an image display apparatus 1 which will be described later is mounted on a head H of an observer, the X axis, the Y axis, and the Z axis are set so that the Y axis direction is an up-and-down direction of the head H, the Z axis direction is a right-and-left direction of the head H, and the X axis direction is a front-and-rear direction of the head H.

As illustrated in FIG. 1, the image display apparatus 1 of the embodiment is the head-mounted display (head-mounted type image display apparatus) which has an external appearance like glasses, is used by being mounted on the head H of the observer, and makes the observer visually confirm a state where an image by a virtual image is overlapped with an external image.

As illustrated in FIG. 1, the image display apparatus 1 is provided with a frame 2, a signal generation portion 3, a scanned light emitting portion 4, and a reflecting portion 6.

In addition, as illustrated in FIG. 2, the image display apparatus 1 is provided with a first optical fiber 7, a second optical fiber 8, and a connection portion 5.

In the image display apparatus 1, the signal generation portion 3 generates signal light which is modulated according to image information, the signal light is guided to the scanned light emitting portion 4 via the first optical fiber 7, the connection portion 5, and the second optical fiber 8, the scanned light emitting portion 4 emits scanned light by scanning the signal light two-dimensionally, and the reflecting portion 6 reflects the scanned light toward eyes EY of the observer. Accordingly, the observer can visually confirm the virtual image according to the image information.

In addition, in the embodiment, a case where the signal generation portion 3, the scanned light emitting portion 4, the connection portion 5, the reflecting portion 6, the first optical fiber 7, and the second optical fiber 8 are provided only on a right side of the frame 2, and only the virtual image for the right eye is formed, is described as an example. However, as a left side of the frame 2 is configured similarly to the right side, the virtual image for the right eye and the virtual image for the left eye may be formed together, and only the virtual image for the left eye may be formed.

Hereinafter, each part of the image display apparatus 1 will be described in order.

### Frame

As illustrated in FIG. 1, the frame 2 is in a shape of a glasses frame, and has a function of supporting the signal generation portion 3 and the scanned light emitting portion 4.

In addition, as illustrated in FIG. 1, the frame 2 includes: a front portion 22 which supports the scanned light emitting portion 4 and a nose pad portion 21; a pair of temple portions (hooking portions) 23 which abuts against the ears of a user by being connected to the front portion 22; and a modern portion 24 which is an end portion of each temple portion 23 opposite to the front portion 22.

The nose pad portion 21 abuts against a nose NS of the observer when the apparatus is in use, and supports the image display apparatus 1 with respect to the head of the observer. The front portion 22 includes a rim portion 25 or a bridge portion 26.

The nose pad portion 21 is configured to be capable of adjusting a position of the frame 2 with respect to the observer when the apparatus is in use.

In addition, if the apparatus can be mounted on the head H of the observer, the shape of the frame 2 is not limited to that in the drawing.

### Signal Generation Portion

As illustrated in FIG. 1, the signal generation portion 3 is provided in the modern portion 24 (end portion on aside opposite to the front portion 22 of the temple portion 23) of one side (right side in the embodiment) of the frame 2 described above.

In other words, the signal generation portion 3 is disposed on the side opposite to the eyes EY with respect to the ears EA of the observer when the apparatus is in use. Accordingly, a weight balance of the image display apparatus 1 can be excellent.

The signal generation portion 3 has a function of generating the signal light which is scanned by a light scanning portion 42 of the scanned light emitting portion 4 which will be described later, and a function of generating a driving signal which drives the light scanning portion 42.

As illustrated in FIG. 3, the signal generation portion 3 is provided with a signal light generation portion 31, a driving signal generation portion 32, a control portion 33, an optical detection portion 34, and a fixing portion 35.

The signal light generation portion 31 generates the signal light which is scanned (scanned light) by the light scanning portion 42 (optical scanner) of the scanned light emitting portion 4 which will be described later.

The signal light generation portion 31 has: a plurality of light sources 311R, 311G, and 311B (light source portions) which have different wavelengths from each other; a plurality of driving circuits 312R, 312G, and 312B; lenses 313R, 313G, and 313B; and a light combining portion (combining portion) 314.

The light source 311R (R light source) emits red light, the light source 311G (G light source) emits green light, and the light source 311B emits blue light. By using these three colors of light, it is possible to display a full-colored image.

The light sources 311R, 311G, and 311B are provided with a light emitting device (to be described later) according to the invention. In addition, the light emitting device will be described later.

The light sources 311R, 311G, and 311B are electrically connected to the driving circuits 312R, 312G, and 312B, respectively.

The driving circuit 312R has a function of driving the light source 311R described above, the driving circuit 312G has a function of driving the light source 311G described above, and the driving circuit 312B has a function of driving the light source 311B described above.

The three types (three colors) of light which are emitted from the light sources 311R, 311G, and 311B that are driven by the driving circuits 312R, 312G, and 312B, are incident on the light combining portion 314 via the lenses 313R, 313G, and 313B.

The lenses 313R, 313G, and 313B are respectively collimator lenses. Accordingly, the light emitted from the light sources 311R, 311G, and 311B are respectively formed to be parallel light, and are respectively incident on the light combining portion 314.

The light combining portion 314 combines the light from the plurality of light sources 311R, 311G, and 311B. Accordingly, the number of the optical fibers for transmitting the signal light generated by the signal light generation portion 31 to the scanned light emitting portion 4, can be small. For this reason, in the embodiment, it is possible to transmit the signal light from the signal generation portion 3 to the scanned light emitting portion 4 via one light transmission path which is formed of the first optical fiber 7, the connection portion 5 and the second optical fiber 8.

In the embodiment, the light combining portion 314 has three dichroic mirrors 314a, 314b, and 314c, and emits one ray of signal light by combining the rays of the light (three colors of light, such as the red light, the green light, and the blue light) emitted from the light sources 311R, 311G, and 311B. In addition, hereinafter, the light sources 311R, 311G, and 311B are all together referred to as a “light source portion 311”. The signal light generated by the signal light generation portion 31 is referred to as “light emitted from the light source portion 311”.

In addition, the configuration of the light combining portion 314 is not limited to the configuration in which the above-described dichroic mirrors are used, and for example, may be a configuration in which a prism, an optical waveguide, or an optical fiber is used.

The signal light generated by the signal light generation portion 31 is incident on one end portion of the first optical fiber 7. Then, the signal light passes through the first optical fiber 7, the connection portion 5, and the second optical fiber 8 in order, and is transmitted to the light scanning portion 42 of the scanned light emitting portion 4 which will be described later.

Here, in the vicinity of the end portion (hereinafter, simply referred to as “one end portion of the first optical fiber 7) of an incident side of the signal light of the first optical fiber 7, the optical detection portion 34 is provided. The optical detection portion 34 detects the signal light. In addition, one end portion of the first optical fiber 7 and the optical detection portion 34 are fixed to the fixing portion 35.

The driving signal generation portion 32 generates the driving signal which drives the light scanning portion 42 (optical scanner) of the scanned light emitting portion 4 which will be described later.

The driving signal generation portion 32 includes: a driving circuit 321 (first driving circuit) which generates a first driving signal that is used in scanning (horizontal scanning) in a first direction of the light scanning portion 42; and a driving circuit 322 (second driving circuit) which generates a second driving signal that is used in scanning (vertical scanning) in a second direction orthogonal to the first direction of the light scanning portion 42.

The driving signal generation portion 32 is electrically connected to the light scanning portion 42 of the scanned light emitting portion 4 which will be described later, via a signal line (not illustrated). Accordingly, the driving signal (the first driving signal and the second driving signal) generated by the driving signal generation portion 32 is input into the light scanning portion 42 of the scanned light emitting portion 4 which will be described later.

The above-described driving circuits 312R, 312G, and 312B of the signal light generation portion 31 and the driving circuits 321 and 322 of the driving signal generation portion 32, are electrically connected to the control portion 33.

The control portion 33 has a function of controlling the driving of the driving circuits 312R, 312G, and 312B of the signal light generation portion 31 and the driving circuits 321 and 322 of the driving signal generation portion 32, based on a video signal (image signal). In other words, the control portion 33 has a function of controlling the driving of the scanned light emitting portion 4. Accordingly, the signal light generation portion 31 generates the signal light which is modulated according to the image information, and the driving signal generation portion 32 generates the driving signal according to the image information.

In addition, the control portion 33 is configured to be capable of controlling the driving of the driving circuits 312R, 312G, and 312B of the signal light generation portion 31, based on an intensity of light detected by the optical detection portion 34.

### Scanned Light Emitting Portion

As illustrated in FIGS. 1 and 2, the scanned light emitting portion 4 is installed in the vicinity (that is, the vicinity of the center of the front portion 22) of the bridge portion 26 of the above-described frame 2.

As illustrated in FIG. 4, the scanned light emitting portion 4 is provided with a housing 41 (case), a light scanning portion 42, a lens 43 (coupling lens), a lens 45 (condenser lens), and a supporting member 46.

The housing 41 is installed in the front portion 22 via the supporting member 46.

In addition, an outer surface of the housing 41 is bonded to a part on a side opposite to the frame 2 of the supporting member 46.

The housing 41 supports the light scanning portion 42 and accommodates the light scanning portion 42. In addition, the lens 43 and the lens 45 are installed in the housing 41, and the lens 43 and the lens 45 constitute a part (a part of a wall portion) of the housing 41.

In addition, the lens 43 (window portion through which the signal light of the housing 41 goes) is separated from the second optical fiber 8. In the embodiment, the end portion on the emitting side of the signal light of the second optical fiber 8 is positioned to face a reflecting portion 10 provided in the front portion 22 of the frame 2, and is separated from the scanned light emitting portion 4.

The reflecting portion 10 has a function of reflecting the signal light emitted from the second optical fiber 8 toward the light scanning portion 42. In addition, the reflecting portion 10 is provided in a concave portion 27 which is open to an inner side of the front portion 22. In addition, the opening of the concave portion 27 may be covered by the window portion which is configured by a transparent material. In addition, if the signal light can be reflected, the configuration of the reflecting portion 10 is not particularly limited. For example, the reflecting portion 10 can be configured by a mirror, a prism, or the like.

The light scanning portion 42 is the optical scanner which scans the signal light from the signal light generation portion 31 two-dimensionally. As the signal light is scanned by the light scanning portion 42, the scanned light is formed. Specifically, the signal light emitted from the second optical fiber 8 is incident on a light reflecting surface of the light scanning portion 42 via the lens 43. According to the driving signal generated by the driving signal generation portion 32, as the light scanning portion 42 is driven, the signal light is scanned two-dimensionally.

In addition, the light scanning portion 42 has a coil 17 and a signal superposition portion 18 (refer to FIG. 4), and the coil 17, the signal superposition portion 18, and the driving signal generation portion 32 constitute a driving portion which drives the light scanning portion 42.

The lens 43 has a function of adjusting a spot diameter of the signal light emitted from the first optical fiber 7. In addition, the lens 43 has a function of adjusting a radiation angle of the signal light emitted from the first optical fiber 7 and substantially parallelizes the angle.

The signal light (scanned light) scanned by the light scanning portion 42 is emitted to the outside of the housing 41 via the lens 45.

### Reflecting Portion

As illustrated in FIGS. 1 and 2, the reflecting portion 6 is installed in the rim portion 25 which is included in the front portion 22 of the above-described frame 2.

In other words, the reflecting portion 6 is disposed to be positioned on a front side of the eyes EY of the observer when the apparatus is in use, and on a side far from the observer even further than and the light scanning portion 42. Accordingly, a part which is projected to the front side of the face of the observer in the image display apparatus 1 can be prevented from being formed.

As illustrated in FIG. 5, the reflecting portion 6 has a function of reflecting the signal light from the light scanning portion 42 toward the eyes of the observer.

In the embodiment, the reflecting portion 6 is a half mirror, and even has a function (translucency with respect to visible light) of making external light go through. In other words, the reflecting portion 6 reflects the signal light from the light scanning portion 42, and has a function of making the external light go through toward the eyes of the observer from the outside of the reflecting portion 6 when the apparatus is in use. Accordingly, the observer can visually confirm the virtual image (image) which is formed by the signal light, while the observer visually confirms the external light. In other words, it is possible to realize a see-through type head-mounted display.

In addition, the reflecting portion 6 may have a diffraction grating, for example. In this case, by giving various optical properties to the diffraction grating, it is possible to reduce the number of components of an optical system, or to enhance flexibility of design. For example, as a hologram element is used as the diffraction grating, it is possible to adjust an emitting direction of the signal light which is reflected by the reflecting portion 6. In addition, by giving a lens effect to the diffraction grating, it is possible to adjust an imaging state of the entire scanned light which is formed from the signal light reflected by the reflecting portion 6.

In addition, the reflecting portion 6 may form a semi-transmissive reflecting film which is configured, for example, by a metal thin film or a dielectric multilayer film on a transparent substrate.

### First Optical Fiber, Optical Detection Portion, and Fixing Portion

The fixing portion 35 has a function of fixing one end portion of the first optical fiber 7 to a position at which the intensity of the light incident on the first optical fiber 7 from the light source portion 311 is greater than zero and equal to or less than a predetermined value. Accordingly, it is possible to make the intensity of the light incident on the first optical fiber 7 from the light source portion 311 small.

In addition, the fixing portion 35 has a function of fixing the optical detection portion 34. Accordingly, it is possible to efficiently use remaining light which is not incident on the first optical fiber 7 among the rays of light (signal light) emitted from the light source portion 311, in the detection of the optical detection portion 34. In addition, it is possible to fix (constantly maintain) a positional relationship between one end portion of the first optical fiber 7 and the optical detection portion 34.

Even when the optical detection portion 34 fixed to the fixing portion 35 in this manner is not provided with the optical system which makes the signal light emitted from the light sources 311B, 311G, and 311R diverge, it is possible to detect the intensity of the emitted light by the optical detection portion 34. In addition, based on the intensity of the light detected by the optical detection portion 34, it is possible to adjust the intensity of the light emitted from the light sources 311B, 311G, and 311R by the control portion 33. In addition, the control portion 33 constitutes a “light control portion” which controls the light sources 311B, 311G, and 311R.

In addition, the embodiment of the image display apparatus according to the invention is not limited to an embodiment having a retina scanning type display principle, such as the above-described head-mounted display. In other words, the embodiment of the image display apparatus according to the invention may have a display principle other than the retina scanning type, such as a heads-up display, a laser projector, or a laser television. Even in a case of these display principles, there is a concern that reflected light is incident on the retina directly or coincidently. Therefore, by the invention, it is possible to expect similar operations and effects to a case of the retina scanning type.

### Light Emitting Device

### First Embodiment

Next, a first embodiment of the light emitting device according to the invention will be described.

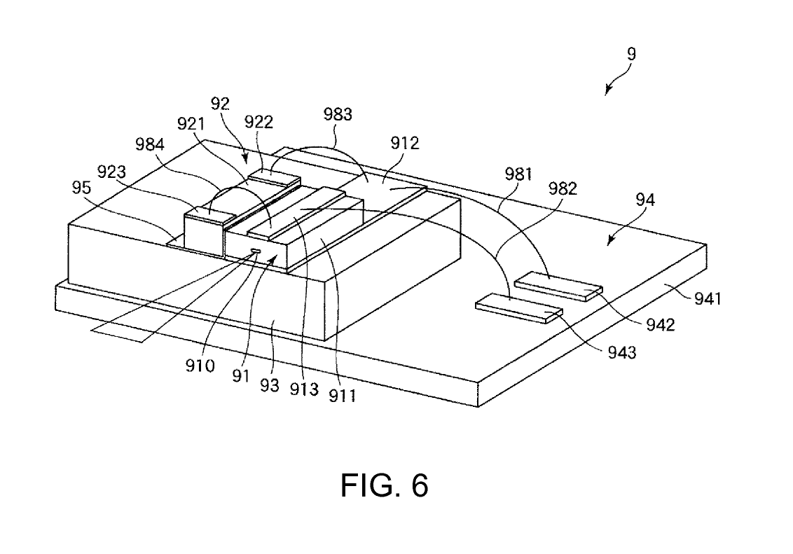

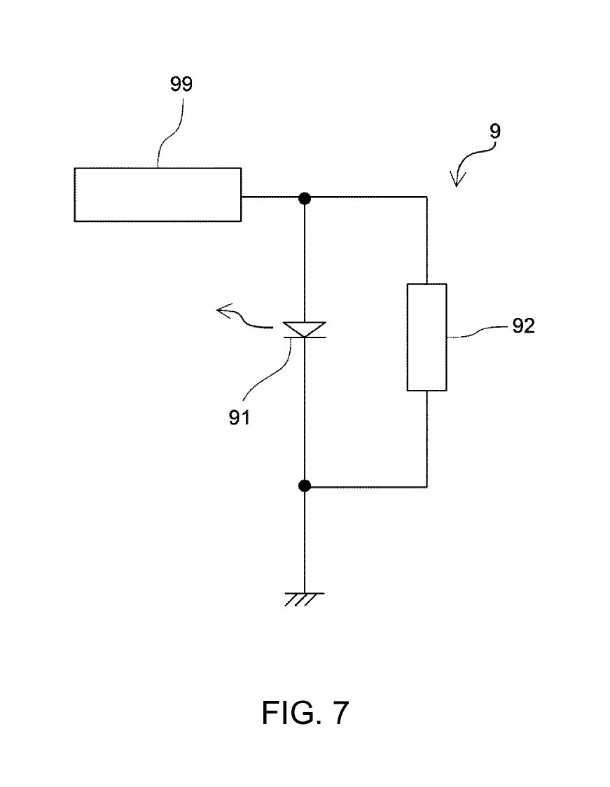

FIG. 6 is a perspective view illustrating a schematic configuration of a first embodiment (light source) of the light emitting device according to the invention. FIG. 7 is a circuit diagram illustrating an example of connection between the light emitting device illustrated in FIG. 6 and a current source. In addition, in the description below, an upside of FIG. 6 will be described as “up”, and a downside of FIG. 6 will be described as “down”.

The above-described light sources 311R, 311G, and 311B are respectively configured by the embodiments of the light emitting device according to the invention.

The light emitting device 9 illustrated in FIG. 6 is provided with a light emitting element 91, a temperature variable resistive element 92, a mount 93, and a mounting substrate 94.

In addition, as illustrated in FIG. 7, the light emitting element 91 and the temperature variable resistive element 92 are connected to each other in parallel. In addition, an anode of the light emitting element 91 is connected to a current source 99, and is electrically grounded to a cathode side. In addition, the current source 99 corresponds to each current source which is provided in the above-described plurality of driving circuits 312R, 312G, and 312B.

### Mounting Substrate

The mounting substrate 94 is a substrate for mounting the mount 93 on which the light emitting element 91 and the temperature variable resistive element 92 are loaded.

The mounting substrate 94 is provided with an insulating substrate 941 and two external electrode terminals 942 and 943 provided on the surface thereof. In addition, although not illustrated in the drawing, there is provided a wiring which is connected to the external electrode terminals 942 and 943. The light emitting element 91 and the current source 99 are connected to each other via the external electrode terminals 942 and 943.

In addition, the mounting substrate 94 can be provided as necessary, and can be omitted.

### Mount

The mount 93 is used as a foundation on which the light emitting element 91 is mounted. In general, the mount is configured by a material having a high thermal conductivity, and has a function of dissipating the heat generated by the light emitting element 91 at high efficiency. In addition, the mount 93 also has high insulation properties, and has a function of ensuring the insulation with the light emitting element 91 and a heat sink (not illustrated) or the like.

As a configuration material of the mount 93, for example, a ceramics material, such as aluminum nitride or silicon carbide, and a metal material, such as copper or aluminum, can be used. In addition, as necessary, the mount 93 is configured by a composite in which a metal layer is formed on one surface or on both surfaces of the substrate made of the ceramics material.

In addition, the heat sink (not illustrated) may be provided between the mount 93 and the mounting substrate 94.

In addition, the mount 93 can be provided as necessary, and can be omitted in a case where the amount of heat from the light emitting element 91 is small, or the like.

### Light Emitting Element

Examples of the light emitting element 91 include semiconductor laser (LD), a super luminescent diode (SLD), a light emitting diode (LED), an organic EL element, an inorganic EL element, or the like. However, an end surface light emitting type semiconductor laser is illustrated as an example in FIG. 6.

In general, a structure of the semiconductor laser is a chip structure in which an electrode or the like is installed on a laminated body which is made by laminating layers configured by a semiconductor material, and has a shape of a rectangular parallelepiped or a shape which is equivalent thereto. The end surface light emitting type semiconductor laser has a configuration in which a resonator for resonating the light is parallel to a semiconductor substrate surface. The reflecting surfaces of the resonator are two cleavage planes of the semiconductor substrate. As the light is extracted from one cleavage plane, the laser is emitted.

The light emitting element 91 illustrated in FIG. 6 has: a semiconductor portion 911 which is configured by the laminated body including an n-type semiconductor layer, an active layer, and a p-type semiconductor layer; a lower electrode 912 which is provided on a lower side of the semiconductor portion 911; and an upper electrode 913 which is provided on an upper side of the semiconductor portion 911. The lower electrode 912 and the upper electrode 913 are respectively configured by semiconductor layers.

The light emitting element 91 is loaded on the mount 93. Accordingly, the lower electrode 912 is interposed between the semiconductor portion 911 and the mount 93. In addition, the lower electrode 912 extends along a longitudinal direction of the light emitting element 91 and along an upper surface of the mount 93, to be protruded from the semiconductor portion 911. Meanwhile, a width of the upper electrode 913 is narrower than a width of the semiconductor portion 911.

In addition, the lower electrode 912 and the external electrode terminal 942 are electrically connected to each other via a bonding wire 981. Meanwhile, the upper electrode 913 and the external electrode terminal 943 are electrically connected to each other via a bonding wire 982. Among the external electrode terminal 942 and the external electrode terminal 943, if the current flows to the anode side of the light emitting element 91, the light is emitted from an emitting portion 910 of the light emitting element 91. In a case of the semiconductor laser, as a composition of the semiconductor material which constitutes the semiconductor portion 911 is changed, it is possible to select a wavelength (color) of the emitted light.

In addition, in the description above, the lower electrode 912, the upper electrode 913, and the semiconductor portion 911 are all together considered as the light emitting element 91. However, examples of the light emitting element 91 is not limited thereto, and for example, a conductive material, such as an AuSn eutectic solder, may be interposed between the lower electrode 912 and the semiconductor portion 911.

In addition, when the mount 93 is made of a metal material or when the mount 93 is made of a ceramics material provided with a metal layer on a surface thereof, since the metal portions function as an electrode, it is possible to omit the lower electrode 912.

### Temperature Variable Resistive Element

The temperature variable resistive element 92 according to the embodiment is a resistive element having a characteristic in which a resistance value decreases as the temperature increases. Examples of the resistive element having such a characteristic include an NTC thermistor, a CTR thermistor, or the like. Among these examples, it is preferable to use the NTC thermistor which is easily made small and has high responsiveness.

In the embodiment, the light emitting element 91 and the temperature variable resistive element 92 are disposed to be close to each other so that the heat conduction between the light emitting element 91 and the temperature variable resistive element 92 can be performed easily. For this reason, when the heat is generated as the light emitting element 91 is driven, the heat is conducted to the temperature variable resistive element 92, and the temperature of the temperature variable resistive element 92 increases. When the temperature of the temperature variable resistive element 92 increases, the resistance value of the element decreases based on the above-described characteristics.

As described above, the light emitting element 91 and the temperature variable resistive element 92 are connected to each other in parallel. For this reason, the current, which flows through a line on the light emitting element 91 side before the increase in the temperature, flows through a line on the temperature variable resistive element 92 side as the resistance value of the temperature variable resistive element 92 decreases after the increase in the temperature. As a result, the current which flows through the line on the light emitting element 91 side decreases.

In the semiconductor laser or the like, a driving current and an amount of light are substantially in a proportional relationship. For this reason, when the current which flows through the line on the light emitting element 91 side decreases, the amount of light of the light emitting element 91 decreases. Accordingly, the amount of light of the light emitting element 91 is prevented from being increased any more.

The above-described behavior is based on basic characteristics of the temperature variable resistive element 92 which is one of passive elements, and differs from a behavior based on an operation of an active element which is called an IC including an electronic circuit. In addition, the temperature variable resistive element 92 can be considered as an element having a high tolerance with respect to an environment change, such as a temperature change or a shock, compared to the IC or the like, and having an extremely low failure probability. For this reason, according to the embodiment, it is possible to suppress the amount of the light emitted from the light emitting element 91 to be equal to or lower than a certain value without following a calculation or the like. Therefore, it is possible to sufficiently secure safety of the light emitting device 9. In other words, in the image display apparatus 1 which causes the signal light to be directly incident toward the eyes EY of the observer, even if the current which flows in the light emitting element 91 is extremely high, since the current can be quickly suppressed and the amount of light can be suppressed to be equal to or less than the certain amount, it is possible to suppress an adverse effect on the retina of the observer to a minimum.

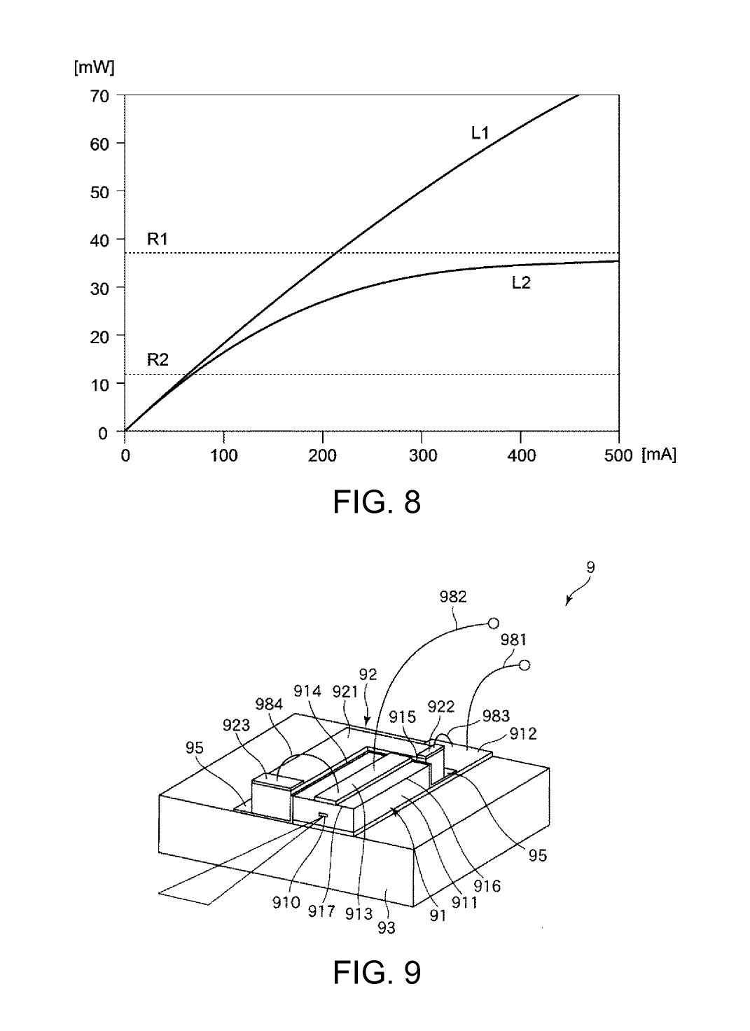

FIG. 8 is a schematic view illustrating a difference of a relationship between the driving current and the amount of light of the light emitting element, according to a presence or an absence of the temperature variable resistive element. In addition, a dotted line R1 illustrated in FIG. 8 is a line illustrating an example of an upper limit of the amount of light which does not have an adverse effect on the retina. In addition, a dotted line R2 illustrated in FIG. 8 is a line illustrating an example of the upper limit of the amount of light which is used at a normal time in the image display apparatus 1.

When the temperature variable resistive element 92 is not provided, as the current which flows in the light emitting element 91 increases, the amount of the light emitted from the light emitting element 91 increases, being substantially proportional to the current, as illustrated as a solid line L1. For this reason, when the solid line L1 exceeds the dotted line R1, there is a concern about an adverse effect on the retina.

Meanwhile, when the temperature variable resistive element 92 is provided, as illustrated as a solid line L2 in FIG. 8, at first, the amount of light increases as the current which flows in the light emitting element 91 increases. However, a ratio of increase in the amount of light gradually deteriorates. Finally, the amount of light reaches a state where the amount of light converges on a certain value, or a state (saturated state) where the amount of light is stuck in an extremely slight increase. At this time, it is possible to adjust the saturation level of the amount of light by appropriately selecting an element having a different relationship between the temperature change and the resistance value change. Therefore, if the solid line L2 is set not to exceed the dotted line R1, it is possible to realize the light emitting device 9 which sufficiently secures safety.

In addition, there is a chip type or a reed type in the NTC thermistor. In particular, it is preferable to use the chip type NTC thermistor. The chip type NTC thermistor can be easily disposed to be close to the chip type light emitting element 91 illustrated in FIG. 6, and the distance therebetween is easily shortened. For this reason, an area which contributes to the heat conduction between the light emitting element 91 and the temperature variable resistive element 92 becomes large. As a result, the thermal conductivity between the light emitting element 91 and the temperature variable resistive element 92 increases. Therefore, it is possible to reduce the time difference between the light emitting element 91 and the temperature variable resistive element 92 when the temperature increases. Accordingly, after the amount of light of the light emitting element 91 exceeds the certain value, a time lag until the resistance value of the temperature variable resistive element 92 is sufficiently small and the current decreases to an extent that the amount of light of the light emitting element 91 is lower than the certain value, is reduced. This also causes the time for emitting the light having an amount that adversely affects the retina to be a minimum. Accordingly, it is possible to further enhance safety of the light emitting device 9.

In addition, in the light emitting device 9 illustrated in FIG. 6, the light emitting element 91 and the temperature variable resistive element 92 are insulated via the layer-shaped insulator 95. For this reason, even when the light emitting element 91 and the temperature variable resistive element 92 are disposed close to each other, while preventing the generation of a failure, such as a short circuit, it is possible to enhance the thermal conductivity between the light emitting element 91 and the temperature variable resistive element 92.

In addition, from such a viewpoint, as an insulator 95, it is preferable to use a member which has a thermal conductivity. Examples of the insulator 95 having a thermal conductivity include ceramics, a thermally conductive grease, a thermally conductive adhesive, a thermally conductive tape, or the like. Among these, in the viewpoint of insulation properties and adhesiveness, it is preferable to configure the insulator by an epoxy resin or a polyimide resin. Even in a case of the resin material, by making the thickness of the insulator 95 thin, it is possible to sufficiently ensure the thermal conductivity. In addition, in order to enhance the thermal conductivity, there is even a case where a certain amount of conductive particles is added as necessary.

The temperature variable resistive element 92 illustrated in FIG. 6 is an example of the chip type NTC thermistor, and is provided with a thermistor prime field 921 and a pair of terminal electrodes 922 and 923 which is provided on an upper surface thereof. The thermistor prime field 921 is configured by the semiconductor material which has an oxide of a transition metal, such as manganese, nickel, or cobalt, as a main component. As the temperature of the thermistor prime field 921 changes, the resistance value between the terminal electrode 922 and the terminal electrode 923 changes. In addition, as an internal electrode is provided in the thermistor prime field 921 as necessary, the thermistor prime field 921 may have a lamination structure.

In addition, the terminal electrode 922 and the lower electrode 912 of the light emitting element 91 are electrically connected to each other via a bonding wire 983. Meanwhile, the terminal electrode 923 and the upper electrode 913 of the light emitting element 91 are electrically connected to each other via a bonding wire 984. As the temperature variable resistive element 92 and the light emitting element 91 are connected to each other in parallel in this manner, as described above, without largely changing voltage applied to the light emitting element 91, it is possible to reduce the current which flows in the light emitting element 91. For this reason, it is possible to achieve both a stable light emitting and a safety securing of the light emitting element 91.

In addition, in the light emitting device 9 illustrated in FIG. 6, both the light emitting element 91 and the temperature variable resistive element 92 are mounted on the mount 93. For this reason, while a part of the heat from the light emitting element 91 is conducted to the temperature variable resistive element 92, the heat is also conducted to the mount 93. Since the mount 93 generally has a relatively high heat capacity, it is possible to contribute to dissipating the heat of the light emitting element 91.

Meanwhile, the layer-shaped insulator 95 is interposed between the temperature variable resistive element 92 and the mount 93. Accordingly, even when the mount 93 has a conductivity, it is possible to prevent a short circuit between the temperature variable resistive element 92 and the mount 93. In addition, as the insulator 95 has a heat conductivity, heat dissipation properties of the temperature variable resistive element 92 are improved. As a result, the heat conducted from the light emitting element 91 to the temperature variable resistive element 92 remains in the temperature variable resistive element 92, and it is possible to avoid a failure in which the temperature change of the temperature variable resistive element 92 does not sufficiently conform with the temperature change of the light emitting element 91.

In addition, in the light emitting device 9 illustrated in FIG. 6, when the temperature increases, a time difference which is difficult to be compensated is generated between the light emitting element 91 and the temperature variable resistive element 92. During this short period of time, the amount of light of the light emitting element 91 remains to be above the certain value. Meanwhile, if the time difference is short like this, even when the amount of light is above regulatory limits, it is considered that an adverse effect on the retina is small.

Here, during the short time period until the current which flows in the light emitting element 91 is defined, the light having a large amount is emitted from the light emitting element 91. Therefore, in the light emitting device 9, the light having a large amount may be used as light which is emitted to send a command of warning. As such a warning (alarm) is generated, the user of the light emitting device 9, that is, the user of the image display apparatus 1 can know an abnormality of the light emitting device 9. For example, it is possible to obtain a chance to take an action, such as restraining the use of the apparatus for a certain period of time, or inspecting and repairing the light emitting device 9.

### Second Embodiment

Next, a second embodiment of the light emitting device according to the invention will be described.

FIG. 9 is a perspective view illustrating the second embodiment of the light emitting device according to the invention.

Hereinafter, the second embodiment will be described, but in the description below, differences from the above-described first embodiment will be mainly described, and similar parts and the description thereof will be omitted. In addition, in the drawing, the same configuration as that of the above-described embodiment is given the same reference numerals. In addition, in FIG. 9, the illustration of the mounting substrate 94 will be omitted.

The second embodiment is similar to the first embodiment except that the shape of the temperature variable resistive element 92 is different.

As illustrated in FIG. 9, the shape in a planar view of the temperature variable resistive element 92 according to the second embodiment is a shape in which a part between the terminal electrode 922 and the terminal electrode 923 is bent by 90 degrees in the middle thereof. Specifically, while the shape in a planar view of the light emitting element 91 as illustrated in FIG. 9 is a rectangle (oblong), the temperature variable resistive element 92 has a shape along a first side surface which corresponds to a rectangular first side 914 and a second side surface which corresponds to a second side 915 that is adjacent to the first side 914. In other words, since the light emitting element 91 illustrated in FIG. 9 is in a rectangular shape, and the temperature variable resistive element 92 illustrated in FIG. 9 is in a shape which is bent by 90 degrees, the two sides of the light emitting element 91 and the two sides of the temperature variable resistive element 92 are interlaced with each other by being fitted into each other. In addition, in the specification, the rectangle means a quadrilateral or the like including not only an oblong but also a square. In addition, in the specification, “along” means that the facing surfaces are not required to be parallel to each other and may be nonparallel to each other.

By this configuration, between the light emitting element 91 and the temperature variable resistive element 92, an area at which the light emitting element 91 and the temperature variable resistive element 92 face each other becomes large. For this reason, the area which contributes to the thermal conductivity between the light emitting element 91 and the temperature variable resistive element 92 can become large, and an amount of the thermal conduction can be increased. As a result, it is possible to further reduce the time difference between the light emitting element 91 and the temperature variable resistive element 92 when the temperature increases, and to further reduce the emitting time of the light having an amount which adversely affects the retina.

In addition, in the light emitting element 91 illustrated in FIG. 9, among the shapes in a planar view which forms a rectangle, the emitting portion 910 is provided on a fourth side surface which corresponds to a fourth side 917 which faces the second side 915. The light emitted from the emitting portion 910 is used in drawing the image in the image display apparatus 1. The fourth side surface provided with the emitting portion 910 which emits the light is usually called a front end surface.

Meanwhile, when the light emitting element 91 is the end surface light emitting type semiconductor laser, there is an element which is a type that emits the light not only from the front end surface (fourth side surface), but also from the second side surface which is positioned on a side opposite to the fourth side surface. The second side surface is usually called a rear end surface. In the light emitting device 9 illustrated in FIG. 9, the temperature variable resistive element 92 is disposed to face not only the first side surface of the light emitting element 91 but also the rear end surface (second side surface). In this case, as the light emitted from the rear end surface irradiates the temperature variable resistive element 92, the temperature of the temperature variable resistive element 92 increases in accordance with the light absorption. For this reason, in the embodiment, not only the thermal conductivity from the light emitting element 91 but also the light absorption is applied to the process of the temperature increase of the temperature variable resistive element 92. As a result, the rate of temperature increase of the temperature variable resistive element 92 can be improved, and the time difference between the light emitting element 91 and the temperature variable resistive element 92 when the temperature increases can be further reduced. In other words, it is possible to further enhance the response speed until the light emitted from the light emitting device 9 is defined.

In addition, as the light emitted from the front end surface is not influenced at all by the temperature variable resistive element 92, the emitted light becomes light having characteristics which are originally included in the light emitting element 91. For this reason, for example, a problem, such as an insufficient amount of light, is unlikely to be generated, and the light emitting device 9 contributes to realizing the image display apparatus 1 which is capable of displaying an excellent image.

Even in the second embodiment, similar operations and effects to those of the first embodiment can be obtained.

### Third Embodiment

Next, a third embodiment of the light emitting device according to the invention will be described.

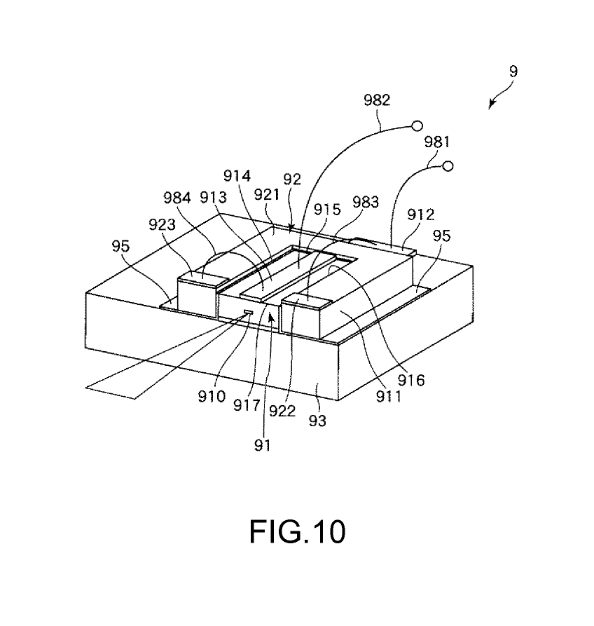

FIG. 10 is a perspective view illustrating the third embodiment of the light emitting device according to the invention.

Hereinafter, the third embodiment will be described, but in the description below, differences from the above-described first and second embodiments will be mainly described, and similar parts and the description thereof will be omitted. In addition, in the drawing, the same configuration as that of the above-described embodiment is given the same reference numerals. In addition, in FIG. 10, the illustration of the mounting substrate 94 will be omitted.

The third embodiment is also similar to the second embodiment except that the shape of the temperature variable resistive element 92 is different.

As illustrated in FIG. 10, the shape in a planar view of the temperature variable resistive element 92 according to the third embodiment is a shape in which the part between the terminal electrode 922 and the terminal electrode 923 is bent two times by 90 degrees in the middle thereof. Specifically, while the shape in a planar view of the light emitting element 91 as illustrated in FIG. 10 is a rectangle (oblong), the temperature variable resistive element 92 has a shape along the first side surface which corresponds to the rectangular first side 914, the second side surface which corresponds to the second side 915 that is adjacent to the first side 914, and a third side surface which corresponds to a third side 916 that is adjacent to the second side 915. In other words, since the light emitting element 91 illustrated in FIG. 10 is in a rectangular shape, and the temperature variable resistive element 92 illustrated in FIG. 10 is in a shape which is bent by 180 degrees, the three side surfaces of the light emitting element 91 and the three side surfaces of the temperature variable resistive element 92 are interlaced with each other by being fitted into each other.

By this configuration, between the light emitting element 91 and the temperature variable resistive element 92, an area at which the light emitting element 91 and the temperature variable resistive element 92 face each other becomes large. For this reason, the area which contributes to the thermal conductivity between the light emitting element 91 and the temperature variable resistive element 92 can be large, and an amount of the thermal conduction can be increased. As a result, it is possible to further reduce the time difference between the light emitting element 91 and the temperature variable resistive element 92 when the temperature increases, and to further reduce the emitting time of the light having an amount which adversely affects the retina.

Even in the third embodiment, similar operations and effects to those of the first embodiment can be obtained.

In addition, in the third embodiment, since the temperature variable resistive element 92 is disposed to surround the light emitting element 91, a position shift of the light emitting element 91 and the temperature variable resistive element 92 is unlikely to occur. For this reason, even when a vibration or the like is applied, it is easy to maintain the thermal conductivity between the light emitting element 91 and the temperature variable resistive element 92, and efficiency is extremely high in the viewpoint of securing safety.

### Fourth Embodiment

Next, a fourth embodiment of the light emitting device according to the invention will be described.

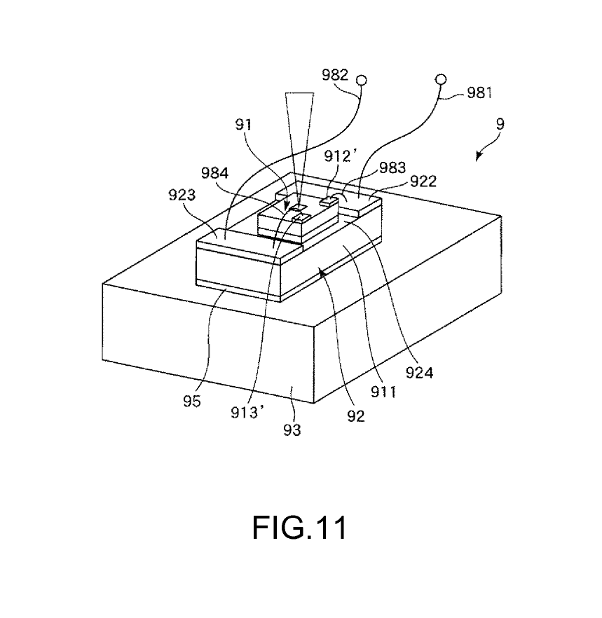

FIG. 11 is a perspective view illustrating the fourth embodiment of the light emitting device according to the invention.

Hereinafter, the fourth embodiment will be described, but in the description below, differences from the above-described first to third embodiments will be mainly described, and similar parts and the description thereof will be omitted. In addition, in the drawing, the same configuration as that of the above-described embodiment is given the same reference numerals. In addition, in FIG. 11, the illustration of the mounting substrate 94 will be omitted.

The fourth embodiment is similar to the first embodiment except that the type of the light emitting element 91 is different.

The light emitting element 91 according to the fourth embodiment is a surface light emitting type semiconductor laser. The surface light emitting type semiconductor laser has a resonator which is perpendicular to the semiconductor substrate surface for resonating the light. The surface light emitting type semiconductor laser has high light emitting efficiency compared to the end surface light emitting type semiconductor laser. In addition, since fast modulation is possible, the surface light emitting type semiconductor laser is advantageous as a light emitting element which is used, in particular, in the image display apparatus.

In addition, in the fourth embodiment, as illustrated in FIG. 11, the light emitting element 91 and the temperature variable resistive element 92 are provided to be overlapped with each other. Specifically, the light emitting element 91 is mounted on an upper surface 924 of the temperature variable resistive element 92. As a result, the temperature variable resistive element 92 is interposed between the light emitting element 91 and the mount 93. In this configuration, the heat generated from the light emitting element 91 can be conducted to the temperature variable resistive element 92 almost without a dissipation of the heat. For this reason, the amount of heat which can be consumed in increasing the temperature of the temperature variable resistive element 92 becomes much larger, and as a result, it is possible to increase a rate of temperature increase of the temperature variable resistive element 92, that is, to reduce the time difference between the light emitting element 91 and the temperature variable resistive element 92 when the temperature increases.

Meanwhile, in the temperature variable resistive element 92, a surface on a side opposite to an upper surface 924 on which the light emitting element 91 is mounted faces the mount 93. For this reason, the heat conducted from the light emitting element 91 to the temperature variable resistive element 92 can be considered to be passed through the temperature variable resistive element 92 and spread to the mount 93 relatively quickly. As a result, the heat in the temperature variable resistive element 92 is unlikely to remain, and conformability of the temperature change of the temperature variable resistive element 92 with respect to the temperature change of the light emitting element 91 is excellent.

In addition, the light emitting element 91 is provided with a first electrode 912′ and a second electrode 913′ on the upper surface thereof. The first electrode 912′ and the terminal electrode 922 of the temperature variable resistive element 92 are electrically connected to each other via the bonding wire 983. Meanwhile, the second electrode 913′ and the terminal electrode 923 of the temperature variable resistive element 92 are electrically connected to each other via the bonding wire 984.

In addition, the light emitting element 91 and the temperature variable resistive element 92 are electrically insulated via the layer-shaped insulator 95, as illustrated in FIG. 11. However, as the insulator 95 has a thermal conductivity, it is possible to suppress deterioration of the rate of temperature increase of the temperature variable resistive element 92.

Even in the fourth embodiment, similar operations and effects to those of the first embodiment can be obtained.

### Fifth Embodiment

Next, a fifth embodiment of the light emitting device according to the invention will be described.

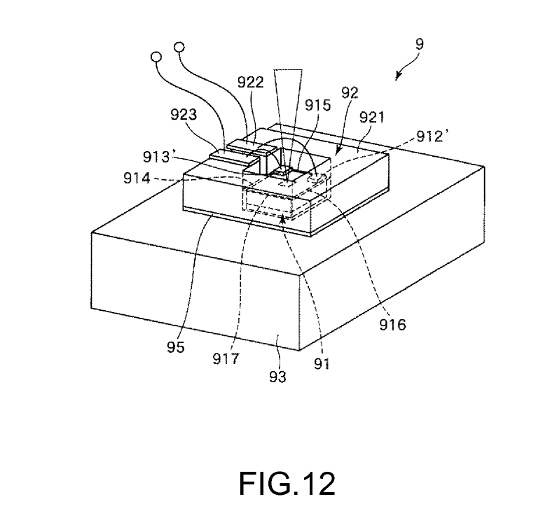

FIG. 12 is a perspective view illustrating the fifth embodiment of the light emitting device according to the invention.

Hereinafter, the fifth embodiment will be described, but in the description below, differences from the above-described first to fourth embodiments will be mainly described, and similar parts and the description thereof will be omitted. In addition, in the drawing, the same configuration as that of the above-described embodiment is given the same reference numerals. In addition, in FIG. 12, the illustration of the mounting substrate 94 will be omitted.

The fifth embodiment is similar to the fourth embodiment except that the shape of the temperature variable resistive element 92 is different.

As illustrated in FIG. 12, the shape in a planar view of the temperature variable resistive element 92 according to the fifth embodiment is a frame shape in which a part thereof is open. Specifically, while the shape in a planar view of the light emitting element 91 illustrated in FIG. 12 is a rectangle (oblong), the temperature variable resistive element 92 has a shape along the first side surface which corresponds to the rectangular first side 914, the second side surface which corresponds to the second side 915 that is adjacent to the first side 914, the third side surface which corresponds to the third side 916 that is adjacent to the second side 915, and a fourth side surface which corresponds to a fourth side 917 that is adjacent to the third side 916. In other words, since the light emitting element 91 illustrated in FIG. 12 is in a rectangular shape, and the temperature variable resistive element 92 illustrated in FIG. 12 is in a frame shape, the light emitting element 91 and the temperature variable resistive element 92 are interlaced as the four side surfaces of the light emitting element 91 are surrounded by the temperature variable resistive element 92.

By this configuration, between the light emitting element 91 and the temperature variable resistive element 92, an area at which the light emitting element 91 and the temperature variable resistive element 92 face each other becomes large. For this reason, the area which contributes to the thermal conductivity between the light emitting element 91 and the temperature variable resistive element 92 can also become large, and an amount of the thermal conduction can be increased. As a result, it is possible to further reduce the time difference between the light emitting element 91 and the temperature variable resistive element 92 when the temperature increases, and to further reduce the emitting time of the light having an amount which adversely affects the retina.

Even in the fifth embodiment, similar operations and effects to those of the fourth embodiment can be obtained.

In addition, in the fifth embodiment, since the temperature variable resistive element 92 is disposed to surround the light emitting element 91, a position shift of the light emitting element 91 and the temperature variable resistive element 92 is unlikely to occur. For this reason, even when a vibration or the like is applied, it is easy to maintain the thermal conductivity between the light emitting element 91 and the temperature variable resistive element 92, and efficiency is extremely high in the viewpoint of securing safety.

### Sixth Embodiment

Next, a sixth embodiment of the light emitting device according to the invention will be described.

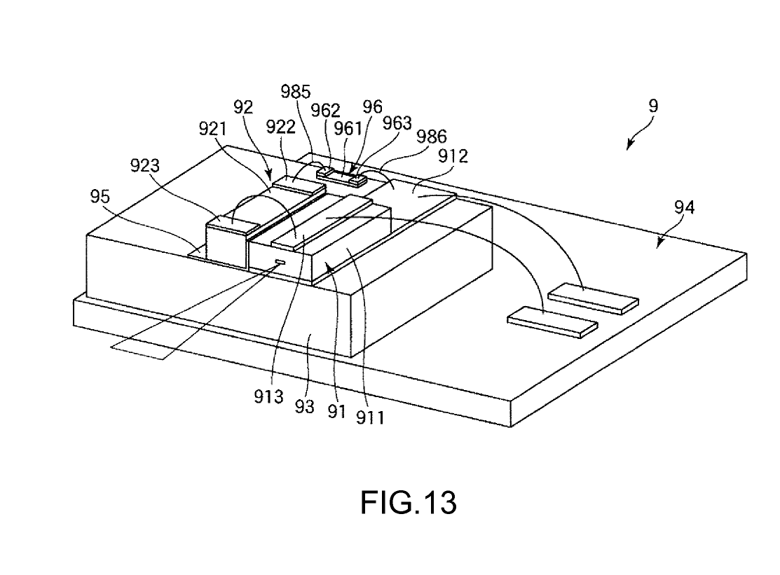

FIG. 13 is a perspective view illustrating the sixth embodiment of the light emitting device according to the invention.

Hereinafter, the sixth embodiment will be described, but in the description below, differences from the above-described first to fifth embodiments will be mainly described, and similar parts and the description thereof will be omitted. In addition, in the drawing, the same configuration as that of the above-described embodiment is given the same reference numerals.

The sixth embodiment is similar to the first embodiment except that a resistive element 96 which is connected to the temperature variable resistive element 92 in series is provided.

As illustrated in FIG. 13, the light emitting device 9 according to the sixth embodiment is provided with the resistive element 96 mounted on the mount 93.

The resistive element 96 illustrated in FIG. 13 has: a resistance portion 961; a terminal electrode 962 which is provided at one end thereof; and a terminal electrode 963 which is provided at the other end thereof. The terminal electrode 922 of the temperature variable resistive element 92 and the terminal electrode 962 of the resistive element 96 are electrically connected to each other via a bonding wire 985. Meanwhile, the lower electrode 912 of the light emitting element 91 and the terminal electrode 963 of the resistive element 96 are electrically connected to each other via a bonding wire 986.

As the resistive element 96 is connected to the temperature variable resistive element 92 in series, the resistive element 96 functions as the detection portion which detects the amount of the current which flows in the temperature variable resistive element 92. In other words, when the current flows through the line on the temperature variable resistive element 92 side, a potential difference is generated according to the resistance value between the terminal electrodes of the resistive element 96. For this reason, as the potential difference is measured, it is possible to estimate the amount of the current which flows in the temperature variable resistive element 92.

As the amount of the current is detected in this manner, the amount of the current which flows through the line on the light emitting element 91 side can be estimated. For this reason, it is possible to indirectly assume the amount of light of the light emitting element 91. Accordingly, it is possible to easily find the amount of light of the light emitting element 91. In addition, in the image display apparatus 1, since data for comparing a current value assigned to the light source by the control portion 33 and a current value which flows in the light emitting element 91 can be acquired, it is possible to perform the detection which is called confirming an integrity of the light emitting element 91, for example.

In addition, there is a case where the resistive element 96 is called shunt. The resistance value varies according to the voltage or the current applied to the circuit, but is set to be equal to or less than 10Ω, for example.

Even in the sixth embodiment, similar operations and effects to those of the first embodiment can be obtained.

Above, the light emitting device and the image display apparatus according to the invention is described based on the embodiments illustrated in the drawing. However, the invention is not limited thereto.

For example, in the light emitting device and the image display apparatus according to the invention, the configurations of each part can be replaced with an arbitrary configuration which shows similar functions. In addition, an arbitrary configuration can be added.

In addition, among the above-described embodiments, two or more embodiments may be combined. For example, even when the light emitting element is the end surface light emitting type element, the light emitting element and the temperature variable resistive element may be overlapped with each other. Furthermore, the resistive element which is connected to the temperature variable resistive element in series can also be added to each embodiment.

The entire disclosure of Japanese Patent Application No. 2013-243182, filed Nov. 25, 2013 is expressly incorporated by reference herein.

What is claimed is:

1. A light emitting device, comprising:
a light emitting element; and
a temperature variable resistive element which is connected to the light emitting element in parallel and is provided so that heat of the light emitting element can be conducted,
wherein the temperature variable resistive element has a characteristic in which a resistance value decreases as a temperature increases.

2. The light emitting device according to claim 1, further comprising:
an insulator having a thermal conductivity, which is provided between the light emitting element and the temperature variable resistive element.

3. The light emitting device according to claim 1,
wherein the light emitting element and the temperature variable resistive element are overlapped with each other.

4. The light emitting device according to claim 1, wherein
the light emitting element has a shape of a rectangle in a planar view, and
the temperature variable resistive element is provided along a first side surface which corresponds to one side of the rectangle and a second side surface which is adjacent to the first side surface.

5. The light emitting device according to claim 1, wherein
the light emitting element has a shape of a rectangle in a planar view, and
the temperature variable resistive element is provided along a first side surface which corresponds to one side of the rectangle, a second side surface which is adjacent to the first side surface, and a third side surface which is adjacent to the second side surface.

6. The light emitting device according to claim 1, wherein
the light emitting element is an edge emitting type element which emits the light from both a front end surface and a rear end surface, and
the temperature variable resistive element is provided along the rear end surface.

7. The light emitting device according to claim 1, wherein
the light emitting element is a surface emitting type element, and
the temperature variable resistive element surrounds the side surfaces of the light emitting element.

8. The light emitting device according to claim 1, further comprising:
a mount on which the light emitting element and the temperature variable resistive element are mounted.

9. The light emitting device according to claim 1, further comprising:
a detection portion which is connected to the temperature variable resistive element in series and detects an amount of the current which flows in the temperature variable resistive element.

10. An image display apparatus, comprising:
a current source; and
the light emitting device according to claim 1.

11. An image display apparatus, comprising:
a current source; and
the light emitting device according to claim 2.

12. An image display apparatus, comprising:
a current source; and
the light emitting device according to claim 3.

13. An image display apparatus, comprising:
a current source; and
the light emitting device according to claim 4.

14. An image display apparatus, comprising:
a current source; and
the light emitting device according to claim 5.

15. An image display apparatus, comprising:
a current source; and
the light emitting device according to claim 6.

16. An image display apparatus, comprising:
a current source; and
the light emitting device according to claim 7.

17. An image display apparatus, comprising:
a current source; and
the light emitting device according to claim 8.

18. An image display apparatus, comprising:
a current source; and
the light emitting device according to claim 9.
